(19) United States
(12) Patent Application Publication
(10) Pub. No.: US 2010/0126666 A1
(43) Pub. Date: May 27, 2010

(54) PLASMA PROCESSING APPARATUS

(76) Inventors: Takumi TANDOU, Asaka (JP); Kenetsu Yokogawa, Tsurugashima (JP); Masaru Izawa, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/368,412

(22) Filed: Feb. 10, 2009

(30) Foreign Application Priority Data
Nov. 27, 2008 (JP) 2008-302628

(51) Int. Cl. H01L 21/3065

(52) U.S. Cl. 156/345.27

(57) ABSTRACT

In a plasma processing apparatus; a refrigerant flow passage being formed in the sample table and constituting an evaporator of a cooling cycle and the in-plane temperature of the sample to be processed is controlled uniformly by controlling the enthalpy of the refrigerant supplied to the refrigerant flow passage and thereby keeping the flow mode in the refrigerant flow passage, namely in the sample table, in the state of a gas-liquid two-phase. If by any chance dry out of the refrigerant occurs in the refrigerant flow passage because the heat input of plasma increases with time or by another reason, it is possible to increase speed of a compressor and inhibit the dry out from occurring in the refrigerant flow passage. Further, if the refrigerant supplied to the refrigerant flow passage is liquefied, it is kept in the gas-liquid two-phase state.

### CLAIM OF PRIORITY

The present application claims priority from Japanese Patent Application 2008-302628 filed on Nov. 27, 2008, the content of which is hereby incorporated by reference into this application.

### FIELD OF THE INVENTION

The present invention relates to a plasma processing apparatus and a plasma processing method for applying microprocessing to a sample such as a wafer in a semiconductor production process and in particular to a temperature controller and a temperature controlling method for controlling a temperature of an electrode to retain and fix a semiconductor wafer.

### BACKGROUND OF THE INVENTION

As semiconductor devices become miniaturized, processing accuracy required for the etching of a sample increases. It is important to control the temperature of a wafer surface during etching in order to form a fine pattern on the wafer surface with a high degree of accuracy with a plasma processing apparatus. However, because of the demands for the increase of a wafer area and the improvement of an etching rate, the high-frequency power applied to a plasma processing apparatus tends to increase. In particular, in etching of a dielectric film layer, a high power in the order of kilowatts is now staring to be applied. Because of the application of a high power, the impact energy of ions on a wafer surface increases and an excessive temperature rise of a wafer is a problem during etching. Further, because of the demand for further improvement of dimensional accuracy, a means for controlling the temperature of a wafer speedy and accurately during processing is desired.

The temperature of a wafer surface in a plasma processing apparatus can be controlled by controlling the temperature of the surface of an electrostatic adsorption electrode (hereunder referred to as an electrode) touching the back surface of the wafer via a heat transfer medium. In such a conventional electrode, the temperature of the surface of the electrode has been controlled by forming a flow passage of a refrigerant in the interior of the electrode and flowing a liquid refrigerant in the flow passage. The liquid refrigerant has been supplied into the electrode flow passage after the liquid refrigerant is adjusted to a target temperature with a cooler or a heater in a refrigerant supplier. In such a refrigerant supplier, since it is configured so as to reserve a liquid refrigerant once in a liquid tank and feed the liquid refrigerant after the temperature is adjusted and the thermal capacity of the liquid refrigerant itself is large, the refrigerant supplier is effective for keeping a wafer surface to a constant temperature. However, such a refrigerant supplier is poor in temperature response, hard in high-speed temperature control, and low in heat transfer efficiency. For that reason, it has been difficult to control a wafer surface to an optimum temperature in response to the upsizing of a device accompanying the recent trend of high heat input and the progress of etching.

In view of the above situation, a direct-expansion type refrigerant supplier (hereunder referred to as a direct-expansion type cooling cycle) wherein a compressor to pressurize a refrigerant, a condenser to condense the pressurized refrigerant, and an expansion valve to expand the refrigerant are installed in an electrode of a refrigerant circulatory system and cooling is carried out by evaporating the refrigerant in a refrigerant flow passage in the electrode is proposed in JP-A No. 89864/2005 for example. In such a direct-expansion type cooling cycle, the cooling efficiency is high because the evaporative latent heat of a refrigerant is used and the evaporation temperature of the refrigerant can be controlled at a high speed by pressure. In the above method, by adopting a direct-expansion type as a refrigerant supplier for an electrode, it is possible to control the temperature of a semiconductor wafer during high heat input etching with high efficiency and at high speed.

### SUMMARY OF THE INVENTION

In a direct-expansion type cooling cycle, cooling is carried out by using latent heat obtained when a refrigerant is evaporated from a liquid into a gas and the evaporation temperature of the refrigerant can be controlled by pressure. In the case where a refrigerant is in the state of a gas-liquid two-phase in a refrigerant flow passage in an electrode, the evaporation temperature is constant as long as the pressure of the refrigerant is constant. In contrast, in the case where the phase change of a refrigerant (for example, from a liquid phase to a gas-liquid two-phase and then to a gas phase) occurs in a refrigerant flow passage, the temperature of the refrigerant cannot be kept constant in the flow passage even when the pressure of the refrigerant is kept constant. As a result, the temperature of an electrode, consequently the in-plane temperature of a sample to be processed on an electrode, cannot be controlled uniformly.

An object of the present invention is to provide a plasma processing apparatus and a plasma processing method that can keep a refrigerant in the state of a gas-liquid two-phase in a flow passage in an electrode in order to control the in-plane temperature of a sample to be processed uniformly by using a direct-expansion type cooling cycle.

Another object of the present invention is to provide a plasma processing apparatus and a plasma processing method that can control the in-plane temperature of a sample to be processed uniformly even in a direct-expansion type heating cycle.

In order to solve the above problems, a plasma processing apparatus according to the present invention has a sample table installed in a vacuum processing chamber, turns a process gas introduced into the vacuum processing chamber into a plasma gas, applies surface processing with the plasma to a sample to be processed mounted on the sample table, in which a cooling cycle having a compressor, a condenser, and an expansion valve installed outside the vacuum processing chamber is structured while a refrigerant flow passage formed in the sample table is used as an evaporator; the refrigerant flow passage has a supply port and a discharge port formed in the sample table and the cross-sectional area of the refrigerant flow passage is formed so as to increase gradually from the supply port toward the discharge port; the plasma processing apparatus includes a refrigerant evaporator controller to control the temperature and the flow rate of the refrigerant for temperature control supplied to and discharged from the refrigerant flow passage of the cooling cycle and a condensing capacity controller to control the heat exchanging capacity of the condenser; and the refrigerant for temperature control is controlled so that the refrigerant for temperature control supplied to the evaporator in the sample table may be kept in the state of a gas-liquid two-phase during the processing of the sample to be processed.

The present invention makes it possible to uniformly control the in-plane temperature of an electrode, consequently the in-plane temperature of a wafer, by adjusting the enthalpy of a refrigerant supplied into an electrode flow passage and keeping the flow mode of the refrigerant in the electrode flow passage in the state of a gas-liquid two-phase flow. More specifically, the present invention makes it possible to inhibit excessive heat exchange between the refrigerant and water for heat exchange, keep the flow mode in the state of a gas-liquid two-phase flow in the electrode flow passage, and control the in-plane temperature of a sample to be processed uniformly by controlling the condensing capacity of the refrigerant immediately before the refrigerant flows into the electrode.

Further, the present invention makes it possible to provide a temperature adjusting unit for a sample table that can uniformly control the in-plane temperature of a wafer when high heat input etching is carried out by applying a high wafer bias electric power with a direct-expansion cycle.

### BRIEF DESCRIPTION OF THE DRAWINGS

FIG. 1A is a schematic diagram showing the configuration of a plasma processing apparatus according to the first embodiment of the present invention;

FIG. 1B is a view showing an example of the functional configuration of a sample table temperature controller in FIG. 1A;

FIG. 2 is a schematic diagram showing a flow passage structure in a sample table according to the first embodiment of the present invention;

FIG. 3A is a graph explaining the characteristic of a refrigerant heat transfer coefficient α in a direct-expansion type cooling cycle according to the first embodiment;

FIG. 3B is a graph explaining the characteristic of a pressure loss ΔP in a direct-expansion type cooling cycle according to the first embodiment;

FIG. 4 is a schematic chart showing an example of the control of a plasma processing apparatus according to the present invention;

FIG. 5A is a graph showing the general characteristic of a refrigerant adopted in the present invention;

FIG. 5B is a graph showing an example of general operations in the case where a heat exhausting capacity controller of a condenser in a cooling cycle adopted in the present embodiment is not operated as a comparative example;

FIG. 5C is a graph showing an example of control in a cooling cycle adopted in the present invention;

FIG. 6A is a schematic diagram showing a method for supplying a refrigerant to a sample table (cooling cycle) according to the second embodiment of the present invention;

FIG. 6B is a schematic diagram showing a method for supplying a refrigerant to a sample table (heating cycle) according to the second embodiment of the present invention;

FIG. 7 is a graph showing an example of control in a heating cycle adopted in the second embodiment of the present invention;

FIG. 8 includes graphs showing the general characteristics of a refrigerant adopted in the third embodiment of the present invention;

FIG. 9 is a schematic diagram showing the general system configuration of a plasma processing apparatus equipped with a means for measuring a void ratio according to the third embodiment of the present invention;

FIG. 10 is a view showing an example of a sight glass adopted in the third embodiment of the present invention; and

FIG. 11 is a schematic diagram showing a flow passage structure in a sample table according to the fourth embodiment of the present invention.

### DETAILED DESCRIPTION OF THE PREFERRED EMBODIMENTS

In a representative embodiment of the present invention, a plasma processing apparatus that turns a process gas introduced into a vacuum processing chamber into a plasma gas and applies surface processing with the plasma to a sample to be processed mounted on a sample table is characterized in that the plasma processing apparatus has a refrigerant flow passage constituting an evaporator of a cooling cycle formed in the sample table and the in-plane temperature of the sample to be processed is controlled uniformly by controlling the enthalpy of a refrigerant supplied into the refrigerant flow passage and thereby keeping the flow mode in the refrigerant flow passage, namely in the sample table, in the state of a gas-liquid two-phase flow.

Further in the present invention, a plasma processing apparatus that turns a material gas introduced into a vacuum chamber having a vacuuming means by a gas introducing means into a plasma gas and applies surface processing with the plasma to a sample to be processed is characterized in that a heating cycle having a compressor, a second heat exchanger, and an expansion valve is structured while the sample table is used as a first heat exchanger and the in-plane temperature of the sample to be processed is controlled uniformly by controlling the enthalpy of a refrigerant supplied into the refrigerant flow passage and thereby keeping the flow mode in the refrigerant flow passage, namely in the sample table, in the state of a gas-liquid two-phase flow.

Here, the temperature adjusting unit in a plasma processing apparatus proposed in the present invention can be applied not only to a plasma etching device but also to a device, such as an ashing apparatus, a sputtering apparatus, an ion implanter, a resist coater, or a plasma CVD apparatus, requiring the in-plane temperature of a wafer to be controlled uniformly at high speed.

Best modes for carrying out the present invention are hereunder explained in detail in reference to the drawings.

### First Embodiment

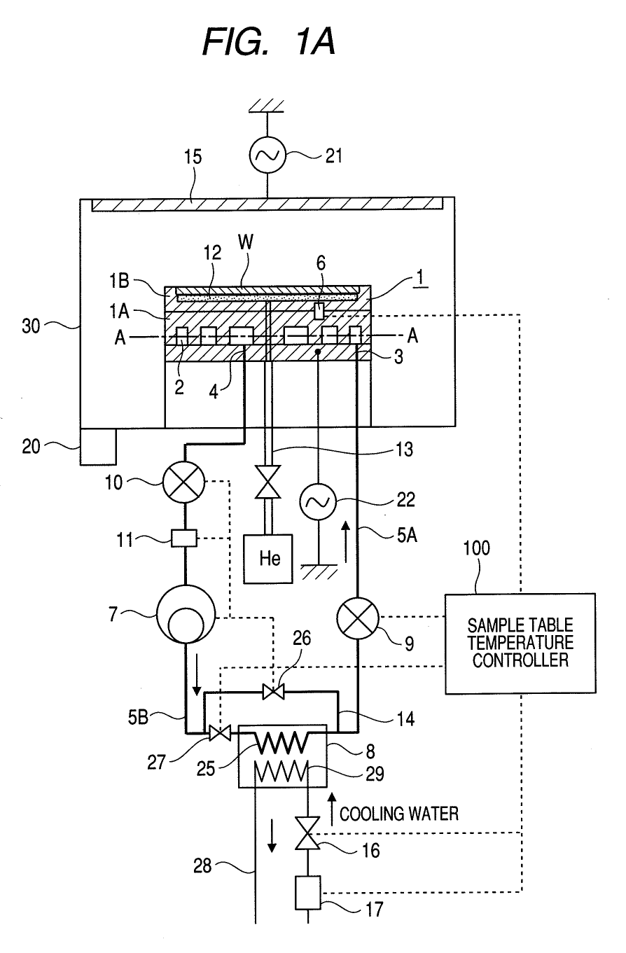

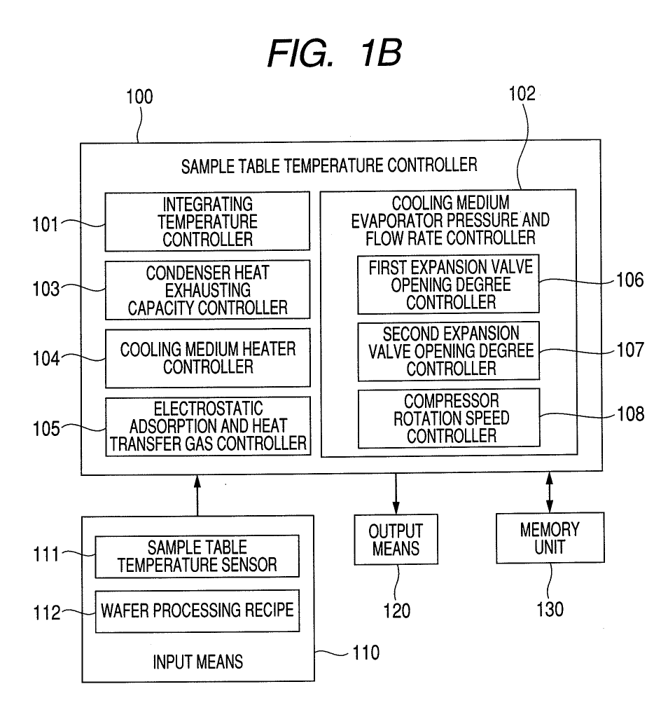

A first embodiment wherein the present invention is applied to a plasma processing apparatus as a cooling cycle to control the temperature of a sample table is explained in reference to FIGS. 1A to 5C.

FIG. 1A is a schematic diagram showing a general system configuration of a plasma processing apparatus according to the first embodiment of the present invention. The plasma processing apparatus has a processing chamber 30 installed in a vacuum chamber and a sample table 1 having an electrostatic adsorption electrode is placed in the processing chamber 30. Further, a vacuum evacuator 20, such as a vacuum pump, to evacuate and decompress the interior thereof is connected to the processing chamber 30. An electrode plate 15 is installed at the upper part of the processing chamber 30 and an antenna power source 21 to supply high-frequency power is connected to the electrode plate 15. Here, at the upper part of the processing chamber 30, a gas introducing means, such as a shower plate, (not shown in the figure) to supply a process gas is installed.

The sample table 1 has a base member part (a lower electrode) 1A and a dielectric film part 1B on which a processed substrate (a wafer) W is stably mounted by electrostatic adsorption. A refrigerant flow passage 2 in which a refrigerant for temperature adjustment circulates is formed in the base material 1A. He gas 12 for heat transfer is supplied from a heat transfer gas supply system 13 into the minute gap between the sample mounting upper surface of the sample table 1 and the back surface of the wafer. A high-frequency bias power source 22 and a DC power source for electrostatic adsorption (not shown in the figure) are connected to the sample table 1.

A refrigerant supply port 3 and a refrigerant discharge port 4 are connected to the refrigerant flow passage 2 formed in the base material 1A of the sample table 1. The refrigerant flow passage 2, together with an entry side refrigerant flow passage 5A, an exit side refrigerant flow passage 5B, a compressor 7, a condenser 8, an electrode entry side expansion valve (hereunder referred to as a first expansion valve) 9, an electrode exit side expansion valve (hereunder referred to as a second expansion valve) 10, and a heater for refrigerant evaporation 11, constitutes a direct-expansion type cooling cycle. Here, the refrigerant flow passage 2 formed in the sample table 1 constitutes an evaporator in the direct-expansion type cooling cycle. That is, the sample table 1 touching the refrigerant is cooled by the latent heat (the vaporization heat) obtained when the refrigerant evaporates in the refrigerant flow passage 2 formed in the sample table 1. As the refrigerant, R410 (hydrofluorocarbon) is used for example. Further, a bypass flow passage 14 bypassing a heat exchanging refrigerant flow passage 25 and a control valve 27 are attached to the condenser 8, and a flow rate valve 16 to control the flow rate of heat exchanging water supplied to a heat exchanging cooling water flow passage 29 in the condenser 8, a temperature controlling water tank 17 to control the temperature of the heat exchanging water, and others are installed in the middle of a cooling water flow passage 28. A control valve 26 to open and close the bypass flow passage 14 is installed in the middle of the passage. Further, the refrigerant evaporating heater 11 includes an electric heater, a heat exchanger similar to the condenser 8, or the like.

The reference numeral 6 represents temperature sensors installed in the sample table at plural positions in proximity to the plane on which a sample is mounted. The reference numeral 100 represents a sample table temperature controller and controls the temperature of the wafer W to be processed on the sample mounting plane so as to come to a target temperature by receiving outputs from the temperature sensors 6 and controlling the heat exhausting capacities of the compressor 7, the first expansion valve 9, the second expansion valve 10, the refrigerant evaporating heater 11, and the condenser 8. The heat exhausting capacity of the condenser 8 is variable by controlling the bypass flow passage 14, the control valves 26 and 27, the flow rate valve 16, the temperature controlling water tank 17, and others. Here, the sample table temperature controller 100 is connected to an upper-stage controller (not shown in the figure) in the plasma processing apparatus. The upper-stage controller has a recipe selector and the plasma processing apparatus and the sample table temperature controller 100 are operated and controlled on the basis of the data of a selected recipe.

The sample table temperature controller 100 is operated by software retained in an arithmetic processor and a memory unit or an I/O means and a memory unit. An example of the functional configuration of a sample table temperature controller is shown in FIG. 1B. The sample table temperature controller 100 has an integrating temperature controller 101 to integrally control all the devices related to a cooling cycle, a pressure and flow rate controller for a refrigerant evaporator (a refrigerant evaporator controller) 102 to control the pressure (=the evaporation temperature) and the flow rate of the refrigerant evaporator (the refrigerant flow passage 2), a condenser heat exhausting capacity controller 103, a refrigerant heater controller 104, an electrostatic adsorption heat transfer gas controller 105, and others in order to control the temperature of the sample table to a temperature suitable for the processing of the wafer W. The refrigerant evaporator pressure and flow rate controller 102 includes a first expansion valve opening degree controller 106 to control the degree of the opening of the first expansion valve 9 located on the entry side of the sample table, a second expansion valve opening degree controller 107 to control the degree of the opening of the second expansion valve 10 located on the exit side of the sample table, a compressor rotation speed controller 108, and others. The sample table temperature controller 100 is further equipped with an input means 110, an output means 120, and a memory unit 130. The condenser heat exhausting capacity controller (condensing capacity controller) 103 controls the heat exchanging capacity (condensing capacity), namely a heat exhausting capacity, of the condenser 8 by controlling the bypass flow passage 14 with the control valves 26 and 27 and controlling the cooling water flow passage 28 with the flow rate valve 16 or the temperature controlling water tank 17. The detection results 111 of the temperature of a wafer W detected with the sample table temperature sensors 6, data of various kinds of recipes 112 to set the process conditions of wafers, and others are input into the sample table temperature controller 100 through the input means 110. The examples of the process conditions are the pressure in the processing chamber 30, the electric power of the antenna power source 21, the electric power of the high-frequency bias power source, the kind and the flow rate of the process gas, the temperature distribution characteristic of the in-plane temperature of a wafer W, and others. The process conditions may be either predetermined or set or changed for each lot of wafers. Further, the cooling cycle constituting devices such as the first expansion valve 9 are controlled by the output coming from the output means 120.

The temperature of the wafer W varies in accordance with processing conditions of plasma etching and the like, namely the state of heat input from plasma to the wafer W. The state of plasma generation, consequently the state of heat input to the wafer W, is determined by the electric energy supplied from the antenna power source 21 and the bias power source 22. Further, the state of heat dissipation from the wafer W is determined by an electrostatic adsorbability, the pressure of a heat transfer gas on the back surface side of the wafer, the temperature of the sample table, and others. Furthermore, when an electric heater is installed in a dielectric film part 1B or the like of the sample table, the calorific value of the heater also has to be taken into consideration. For that purpose, the integrating temperature controller 101 carries out predetermined arithmetic processing on the basis of the processing recipes 112 of the wafer and the temperature detected with the temperature sensors 6 in order to integrally control all the related devices including the direct-expansion type cooling cycle, then the refrigerant evaporator pressure and flow rate controller 102 controls the flow rate, the pressure (the evaporation temperature), and others of the refrigerant flowing in the refrigerant flow passage 2 on the basis of the result, and thereby the temperature of the wafer is controlled so as to be kept at a target temperature. Here, although the electrostatic adsorbability, the pressure of the heat transfer gas on the back surface side of the wafer, the calorific value of the heater, and others also influence the temperature of the wafer, those factors are not the features of the present invention and hence the explanations are omitted hereunder.

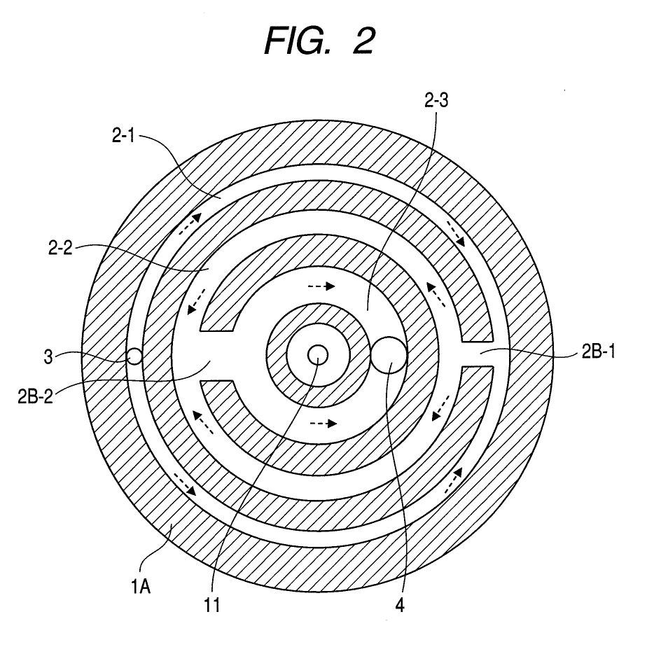

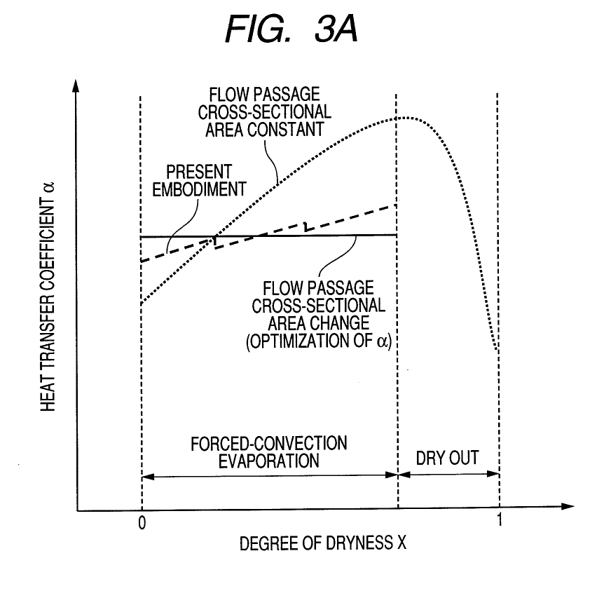

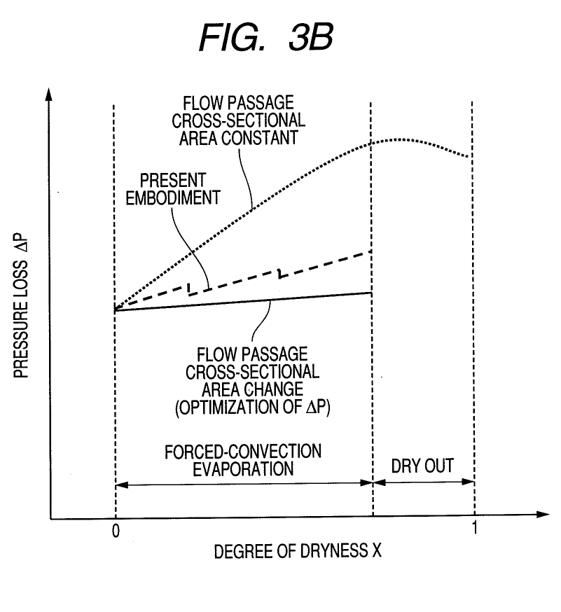

In the present invention, the refrigerant flow passage 2 constituting the evaporator is configured so that the refrigerant flow rate may be controlled in order to avoid the dry out of the refrigerant in the refrigerant flow passage and the cross-sectional area of the refrigerant flow passage may gradually increase from the supply port toward the discharge port. This is explained in reference to FIGS. 2 and 3 (FIGS. 3A and 3B).

FIG. 2 shows a sectional view taken on line A-A in FIG. 1A. In FIG. 2, an annular refrigerant flow passage 2 is formed at a position on an identical height of a base material 1A. The refrigerant flow passage 2 has a first flow passage 2-1 connected to a refrigerant supply port 3 and branched in both the right and left directions, a second flow passage 2-2 connected to a first communication flow passage 2B-1 and branched in both the right and left directions, and a third flow passage 2-3 connected to a second communication flow passage 2B-2 and branched in both the right and left directions, and the third flow passage 2-3 is connected to a refrigerant discharge port 4.

Here, in the adoption of the present invention, the region of the refrigerant flow passage 2 may be diversified if it is desirable that the temperature distribution of the sample table 1 is controlled more uniformly and accurately. For example, a more diversified configuration can be obtained by structuring a refrigerant flow passage 2 with a first flow passage connected to a refrigerant supply port 3 formed at a position close to the outer circumference edge of the sample table 1 and branched in both the right and left directions, a second flow passage connected to a first communication flow passage and branched in both the right and left directions, a third flow passage connected to a second communication flow passage and branched in both the right and left directions, a fourth flow passage connected to a third communication flow passage and branched in both the right and left directions, and a fifth flow passage connected to a fourth communication flow passage and branched in both the right and left directions, and connecting the fifth flow passage to a refrigerant discharge port 4 formed at a position close to the center of the sample table 1. Further, the positions of the refrigerant supply port 3 and the refrigerant discharge port 4 and the dimensional difference in the cross section of the refrigerant flow passage 2 may be reversed.

The refrigerant flows into the refrigerant flow passage 2 from the refrigerant supply port 3 in the state of gas-liquid two-phase, cools the sample table 1 with the evaporative latent heat, and flows out of the refrigerant discharge port 4 in the same state. Since the heat transfer coefficient of the refrigerant changes largely from the refrigerant supply port 3 toward the refrigerant discharge port 4, the refrigerant flow passage 2 is structured so that the cross section may increase from the first flow passage 2-1 toward the third flow passage 2-3 in order to keep the heat transfer coefficient of the refrigerant constant in the refrigerant flow passage 2. By so doing, the flow rate of the refrigerant is lowered in the region of the degree of dryness wherein the heat transfer coefficient of the refrigerant increases and thereby the heat transfer coefficient of the refrigerant is prevented from increasing.

A concrete configuration example is explained in reference to FIG. 3 (FIGS. 3A and 3B).

In the present embodiment, a sample table 1 touching a refrigerant is cooled by the latent heat (vaporization heat) obtained when the refrigerant evaporates in a refrigerant flow passage 2 in the sample table 1. The refrigerant is in the state of a gas-liquid two-phase in the refrigerant flow passage 2 wherein the heat exchange (evaporation) of the refrigerant occurs. That is, when the degree of dryness is represented by X, the expression 0<x<0 is obtained and the evaporation temperature of the refrigerant is theoretically constant as long as the pressure P of the refrigerant is constant in the state. In contrast, the temperature TE of the refrigerant rises basically as the pressure P of the refrigerant increases.

Consequently, in the present invention, the refrigerant temperature TE in the refrigerant flow passage 2 is set by controlling the pressure P of the refrigerant by the degree of opening of expansion valves 9 and 10 and adjusting the refrigerant flow rate Q by the rotation speed of a compressor 7.

The characteristic of the refrigerant heat transfer coefficient α of a direct-expansion type cooling cycle is shown in FIG. 3A and the characteristic of the pressure loss ΔP thereof is shown in FIG. 3B. The graphs of the “flow passage cross-sectional area change” shown with the solid lines in FIGS. 3A and 3B represent the cases where the flow passage cross-sectional areas in plural regions are continuously changed to ideal values on the basis of the present invention and the graphs of the “present embodiment” shown with the thick dotted lines correspond to the flow passage cross-sectional areas expanding stepwise as shown in FIG. 2. Further, the graphs of the “flow passage cross-sectional area constant” shown with the thin dotted lines represent the case of a conventional flow passage configuration, namely the relationship between the degree of dryness X and the heat transfer coefficient α and the degree of dryness X and the pressure loss ΔP in the case where the flow passage cross-sectional area of each region is constant from the inlet 3 toward the outlet 4 of the refrigerant flow passage 2.

In the direct-expansion type cooling cycle, cooling is carried out by using latent heat obtained when a refrigerant evaporates from a liquid to a gas and the evaporation temperature of the refrigerant can be controlled by pressure.

The evaporation temperature TE of a refrigerant does not change even when the ratio of a liquid to a gas (the degree of dryness X) changes as long as the state of the gas-liquid two-phase is maintained and the pressure P is constant. However, when the evaporation of the refrigerant proceeds and the degree of dryness changes, the heat transfer coefficient α changes largely as shown with the thin dotted line in FIG. 3A in the case of the “flow passage cross-sectional area constant.” Meanwhile, when the degree of dryness changes by the evaporation of the refrigerant, the pressure loss ΔP of the refrigerant generated per unit length of the refrigerant flow passage also changes largely as shown with the thin dotted line in FIG. 3B.

In the direct-expansion type cooling cycle, during the process of changing the phase from a liquid to a gas, the heat transfer mode of the refrigerant shifts from forced-convection evaporation to dry out. The forced-convection evaporation starts from the initial stage of the evaporation of the refrigerant and thereafter the heat transfer coefficient α and the pressure loss increase in proportion to the increase of the degree of dryness X. Then when the degree of dryness X of the refrigerant reaches a constant value, dry out (disappearance of a liquid film) occurs and the heat transfer coefficient α and the pressure loss ΔP lower. Here, the pressure loss ΔP does not lower so rapidly as the heat transfer coefficient. Since the heat transfer coefficient α and the pressure loss ΔP of the refrigerant change largely in accordance with the degree of dryness X of the refrigerant in the direct-expansion type cooling cycle as stated above, the control of the temperature distribution in a wafer plane is a technological problem when the direct-expansion type cooling cycle is adopted as a cooling system for the wafer.

As stated above, in order to obtain the uniform in-plane temperature of the wafer by controlling the heat transfer coefficient α and the pressure loss ΔP in accordance with the phase change of the refrigerant, the present invention is configured so that a refrigerant flow rate may be controlled so as not to cause dry out of the refrigerant in the refrigerant flow passage 2 and the cross-sectional area of the refrigerant flow passage 2 in each region may gradually increase from the supply port 3 toward the discharge port 4 in accordance with the phase change of the refrigerant.

That is, the heat transfer coefficient α of a refrigerant is lowered by increasing the flow passage cross-sectional area and thus reducing the flow rate of the refrigerant at a position corresponding to the position where the heat transfer coefficient α of the refrigerant is large, in other words at a region close to the refrigerant discharge port 4, in the general characteristic of the case where the flow passage cross-sectional area is constant as shown in FIG. 3A. By so doing, the flow passage cross-sectional area expands at a position where a pressure loss ΔP is large as shown in FIG. 3B, in other words at a region close to the refrigerant discharge port 4, and that leads to the inhibition of the pressure loss. As a result of the above configuration, it is possible to bring the characteristic of the heat transfer coefficient α from the supply port 3 toward the discharge port 4 of the refrigerant flow passage 2 close to flat and reduce the change of the refrigerant temperature caused by the pressure loss ΔP.

By configuring the cross-sectional area of the refrigerant flow passage 2 formed in the base material 1A so as to gradually increase from the supply port 3 toward the discharge port 4 as stated above, it is possible to equalize the heat transfer coefficient α of the refrigerant in the refrigerant flow passage 2 and inhibit the pressure loss ΔP.

That is, by configuring the cross-sectional area of the refrigerant flow passage 2 so as to gradually increase from the supply port 3 toward the discharge port 4 in the state where the refrigerant flow rate is controlled so as not to cause dry out in the refrigerant flow passage 2, it is possible to inhibit the unevenness of the refrigerant evaporation temperature caused by the pressure loss ΔP and keep the in-plane temperature of the electrode of the sample table 1 uniform while the change of the heat transfer coefficient α caused by the phase change of the refrigerant is mitigated.

Meanwhile, by the method of adopting the structure of continuously changing the cross-sectional area of the refrigerant flow passage in accordance with the phase change of the refrigerant in the refrigerant flow passage, equalizing the refrigerant heat transfer coefficient in the flow passage, reducing the pressure loss, and uniformly controlling the in-plane temperature of a sample to be processed as shown in FIGS. 3A and 3B, it is possible to obtain a desired heat transfer coefficient characteristic in the case where the refrigerant is in the state of a gas-liquid two-phase.

In the case where the refrigerant is in the state of a liquid or a gas, cooling is caused by sensible heat and hence the temperature of the refrigerant changes in accordance with the change of the enthalpy even when the refrigerant pressure is constant. As a result, in order to uniformly control the in-plane temperature of an electrode, consequently the in-plane temperature of the wafer, with a direct-expansion type cooling cycle, it is necessary to optimize the flow passage shape (the cross-sectional area) of the electrode in consideration of the heat transfer coefficient and the pressure loss and simultaneously to configure a temperature adjusting system so that the refrigerant supplied to and discharged from the electrode may be always in the state of a gas-liquid two-phase regardless of the change of process conditions.

In a transitional case in particular, such as the case where it is necessary to rapidly set the plane of the sample table on which a sample is mounted at a desired temperature when the processing of a wafer starts by plasma etching, the case where it is necessary to keep the temperature of the plane on which a sample is mounted constant even when the heat input state to a wafer W changes largely in accordance with the change of a wafer processing recipe, or the case where it is necessary to rapidly change the temperature of the plane on which a sample is mounted to another set temperature in accordance with the change of a processing recipe, the required temperature control characteristics of the sample table must be satisfied. More specifically, it is requested to configure a temperature adjusting system as a temperature adjusting unit suitable for a sample table for microprocessing so that the refrigerant in the sample table may always be in the state of a gas-liquid two-phase even when dynamic temperature change of about 1° C./sec occurs.

The temperature adjusting system according to the present invention makes it possible to always keep the refrigerant in the refrigerant flow passage 2 formed in the sample table in the state of a gas-liquid two-phase and rapidly control the in-plane temperature of a wafer at a desired temperature even in the case where such a dynamic temperature change or a dynamic heat input state change occurs.

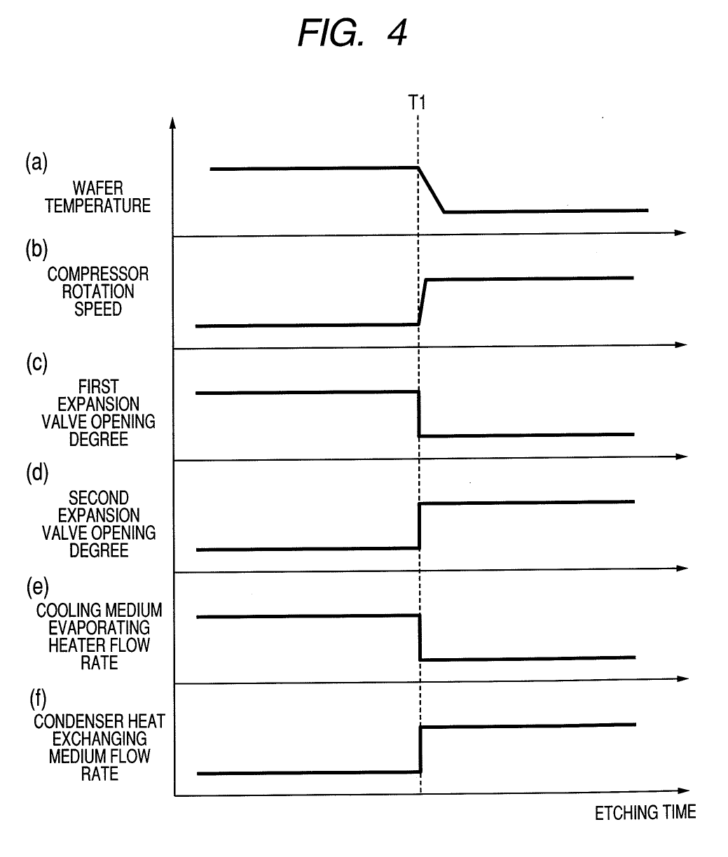

The configuration and operations of a temperature adjusting system according to the present invention are hereunder shown in FIG. 4. A control example is shown here in the case where the sample table temperature controller 100 starts temperature drop control at the time T1 and lowers the temperature of a wafer at a high speed as shown in FIG. 4 (a) in response to the change of the processing conditions of a wafer in a transitional case where the processing conditions change largely, for example in the case where the state of low heat input etching where the bias electric power applied to the wafer is a low or medium level shifts to the state of high bias electric power and high heat input etching.

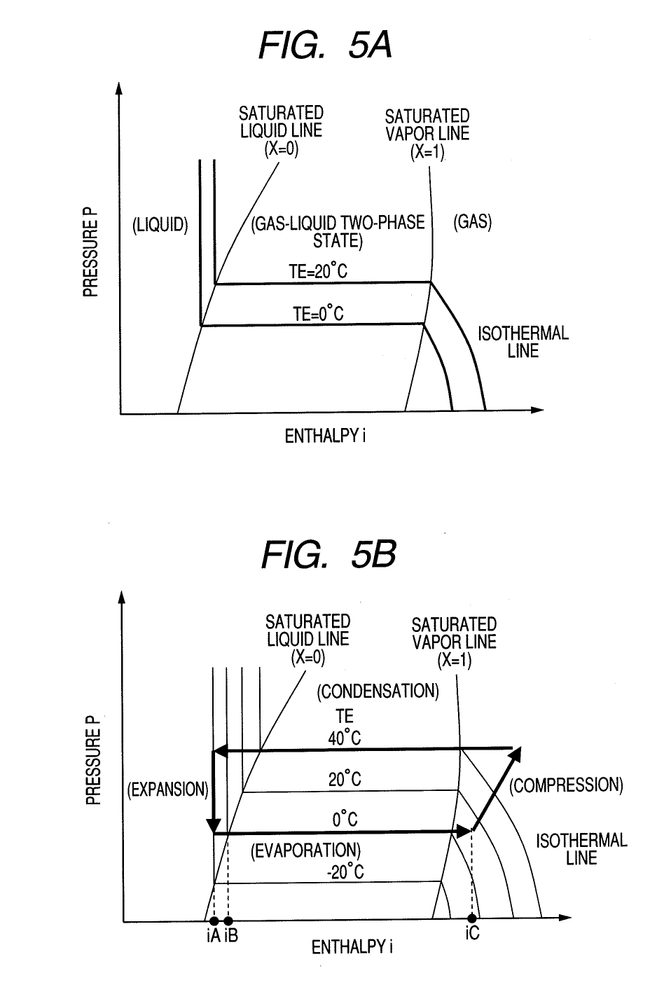

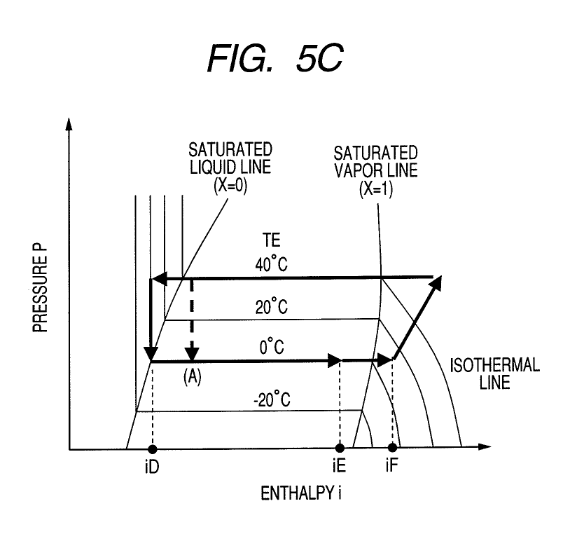

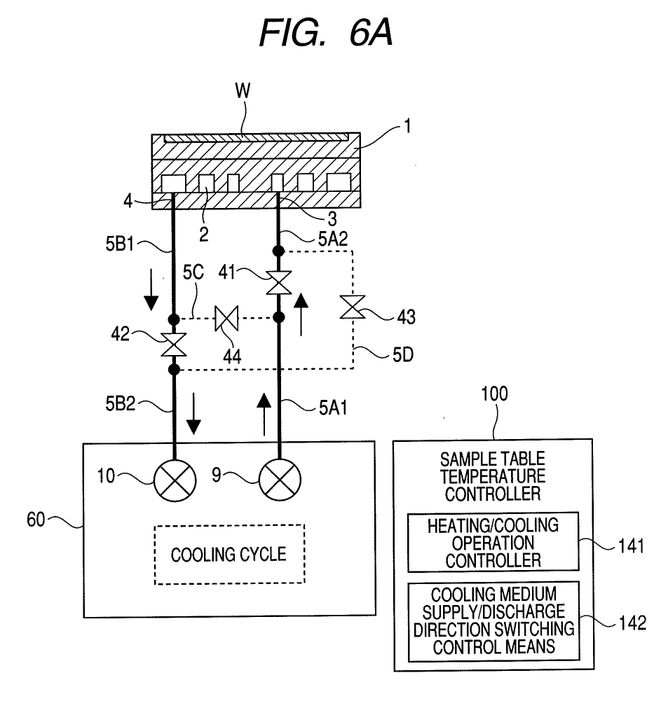

Firstly, the quantity of the refrigerant supplied to the electrode is increased by increasing the rotation speed of the compressor 7 at the time T1 (FIG. 4 (b)) and thus the increase of the heat transfer coefficient of the refrigerant and the occurrence of dry out in the refrigerant flow passage 2 are inhibited. The pressure of the refrigerant is lowered in the electrode flow passage 2 and the evaporation temperature of the refrigerant is also lowered by decreasing the opening degree of the first expansion valve 9 (FIG. 4 (c)) or increasing the opening degree of the second expansion valve 10 (FIG. 4 (d)). On this occasion, it comes to be necessary to lower the wafer temperature and simultaneously lower the temperature of the electrode and the heat quantity recovered by the cooling cycle increases rapidly. As a result, it is necessary to lower the endothermic capacity of the refrigerant evaporating heater 11 (FIG. 4 (e)) and further to increase the heat exhausting capacity (the heat exchange) of the condenser 8 (FIG. 4 (f)). The heat exhausting capacity of the condenser 8 may be increased by either increasing the flow rate or lowering the temperature of the heat exchanging water supplied to the condenser 8 with the flow rate valve 16 or the temperature controlling water tank 17 (the case of flow rate control is shown in FIG. 4). The details on the method for controlling the heat exhausting capacity of the condenser 8 are described below (FIGS. 5A to 5C).

When the wafer temperature is raised at a high speed with the system according to the present invention, the reverse to the control pattern shown in FIG. 4 may be applied. Here, when the heat exhausting capacity of the condenser 8 is reduced perfectly to zero with the bypass flow passage 14 or the like, the cycle is switched from cooling side to heating side.

FIG. 5A is a graph showing the general characteristic of a refrigerant in the cooling cycle adopted in the present embodiment. In the present embodiment, the sample table 1 touching the refrigerant is cooled by using latent heat (vaporization heat) obtained when the refrigerant evaporates in the refrigerant flow passage 2 in the sample table 1 as shown in FIG. 1A. The evaporation temperature (TE) of the refrigerant is theoretically constant as long as the refrigerant pressure (P) is constant when the refrigerant is in the state of a gas-liquid two-phase (the degree of dryness X is larger than 0 and smaller than 1, 0:liquid, 1:gas) in the refrigerant flow passage 2. Basically, the temperature of the refrigerant rises as the pressure of the refrigerant increases. In contrast, when the refrigerant is in the state of a liquid or a gas, the cooling is caused by the sensible heat of the refrigerant and the temperature of the refrigerant changes in accordance with the change of the enthalpy even though the refrigerant pressure is kept constant. In FIG. 5A too, it is confirmed that the temperature (the isothermal line) changes in accordance with the change of the enthalpy in the liquid or gas region. That is, when the state of a saturated liquid or a saturated gas is included in the flow mode of the refrigerant in the refrigerant flow passage 2, it comes to be difficult to uniformly control the electrode in-plane temperature, consequently the wafer in-plane temperature. The enthalpy cited here means the heat quantity that the refrigerant of 1 kg has.

The general characteristic of the cycle in the case where a heat exhausting capacity controller 103 of a condenser in a cooling cycle adopted in the present embodiment is not operated is shown in FIG. 5B as a comparative example. The refrigerant the enthalpy of which has increased by obtaining energy while evaporating in the refrigerant flow passage 2 evaporates thoroughly before long and comes to vapor (a gas region) from the state of a gas-liquid two-phase. Thereafter, the refrigerant is compressed with the compressor, is condensed with the condenser, and exhausts heat, and thereby the flow mode of the refrigerant changes to the liquid state from vapor through the gas-liquid two-phase. The refrigerant of the liquid state is depressurized (expanded) with the first expansion valve 9 and the evaporation temperature of the refrigerant is decided. The refrigerant evaporation temperature TE is constant as long as the refrigerant pressure is constant in the case where the refrigerant is in the state of the gas-liquid two-phase.

Here, in the case where the refrigerant depressurized with the first expansion valve 9 is supplied to the refrigerant flow passage 2 in the state of a liquid as shown in FIG. 5B for example, the temperature of the refrigerant changes in accordance with the change of the enthalpy in the liquid state until the refrigerant reaches the gas-liquid two-phase state. More specifically in reference to FIG. 5B, even though the refrigerant pressure is adjusted in order to set the refrigerant evaporation temperature TE in the refrigerant flow passage 2 at 0° C. (in the gas-liquid two-phase state), the condensation is excessive, hence the refrigerant temperature lowers to −20° C. in the liquid state, and the refrigerant is supplied to the refrigerant flow passage 2. That is, the liquid state refrigerant of −20° C. is supplied to the refrigerant flow passage 2, the refrigerant reaches the gas-liquid two-phase state before long while getting energy, and thereby the refrigerant evaporation temperature TE comes to 0° C. as the set value. While the refrigerant changes from the liquid state of −20° C. to the gas-liquid two-phase state of 0° C., the enthalpy of the refrigerant must increase by iB-iA. In contrast, in the case where the enthalpy increases to iC in the refrigerant flow passage 2 and the refrigerant is vaporized thoroughly as shown in FIG. 5B, the cooling capacity in the region where thoroughly vaporized refrigerant flows lowers rapidly.

As stated above, as long as the flow mode of the refrigerant is not kept in the gas-liquid two-phase state in the refrigerant flow passage 2, the refrigerant temperature is not constant even though the refrigerant pressure is kept constant and the in-plane temperature of the electrode, consequently the in-plane temperature of a wafer, cannot be controlled uniformly.

On the other hand, a method for controlling the flow mode of the refrigerant in the case where the condenser heat exhausting capacity controller 103 is operated in the cooling cycle adopted in the first embodiment of the present invention is shown in FIG. 5C. Here, the case where the refrigerant is kept in the gas-liquid two-phase state and the evaporation temperature of the refrigerant is set at 0° C. in the refrigerant flow passage 2 is shown. Firstly, the refrigerant is discharged while keeping the gas-liquid two-phase state even at the exit of the refrigerant flow passage 2 by supplying the refrigerant to the refrigerant flow passage 2 excessively in comparison with the heat input from plasma. For example, the refrigerant evaporates thoroughly when the enthalpy of the refrigerant increases to iF in FIG. 5C in the refrigerant flow passage 2. For that reason, the enthalpy of the refrigerant may be controlled so as to be about iE in the refrigerant flow passage 2 by increasing the flow rate of the refrigerant with the compressor 7 and the refrigerant discharged from the refrigerant flow passage may be thoroughly evaporated (the enthalpy increases to iF) with the refrigerant evaporating heater 11.

Successively, in the case where the refrigerant supplied to the electrode is kept in the gas-liquid two-phase state, it is necessary to control the condensing capacity and suppress excessive exhaust heat. In FIG. 5C, the enthalpy may be reduced to the isothermal line of 0° C. (iD) in the liquid region. When the condensing capacity is excessive, the temperature of the refrigerant further comes to a temperature lower than 0° C. of the set value in the liquid state. The condensing capacity can be controlled by controlling the flow rate or the temperature of water used for heat exchange in the condenser 8. By so doing, the refrigerant supplied to the refrigerant flow passage 2 through the first expansion valve 9 comes to be in the gas-liquid two-phase state and the temperature of the refrigerant comes to 0° C. Here, although it is also possible to reduce the pressure with the first expansion valve 9 before the refrigerant during condensation reaches the saturated liquid line (the degree of dryness is zero) as shown by (A) in FIG. 5C, if the refrigerant is in the gas-liquid two-phase state (a flash gas state) at the position of the first expansion valve 9, it is concerned that the pressure change characteristic of the refrigerant to the opening degree of the first expansion valve 9 is destabilized and the temperature controllability deteriorates.

In the present embodiment, it is possible to uniformly control the electrode in-plane temperature, consequently the wafer in-plane temperature, by adjusting the enthalpy of the refrigerant supplied into the electrode flow passage and keeping the flow mode of the refrigerant in the electrode flow passage in the state of the gas-liquid two-phase. More specifically, by controlling the evaporating capacity of the refrigerant immediately before the refrigerant flows into the electrode, it is possible to inhibit excessive heat exchange of heat exchanging water with the refrigerant, keep the flow mode in the state of the gas-liquid two-phase in the refrigerant flow passage, and uniformly control the in-plane temperature of a sample to be processed.

In addition, it is possible to control the in-plane temperature of a wafer rapidly and uniformly in quick response to the change of etching conditions. For example, it is possible to provide a temperature adjusting unit for a sample table capable of uniformly controlling the in-plane temperature of a wafer with a direct-expansion type cycle even though etching shifts for a short period of time from the state where a low wafer bias electric power is applied to the state of high heat input etching where a high wafer bias electric power is applied.

### Second Embodiment

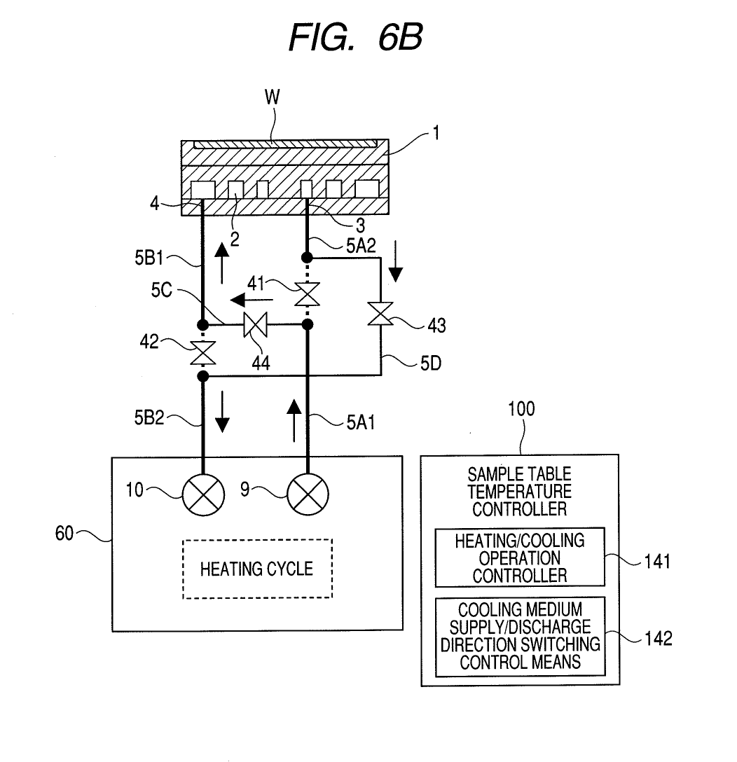

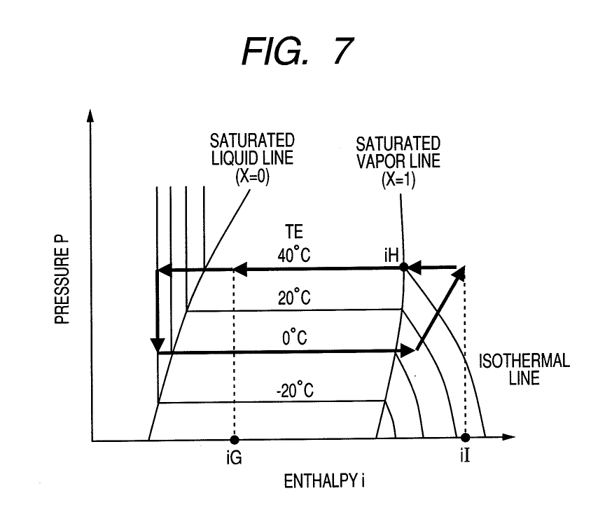

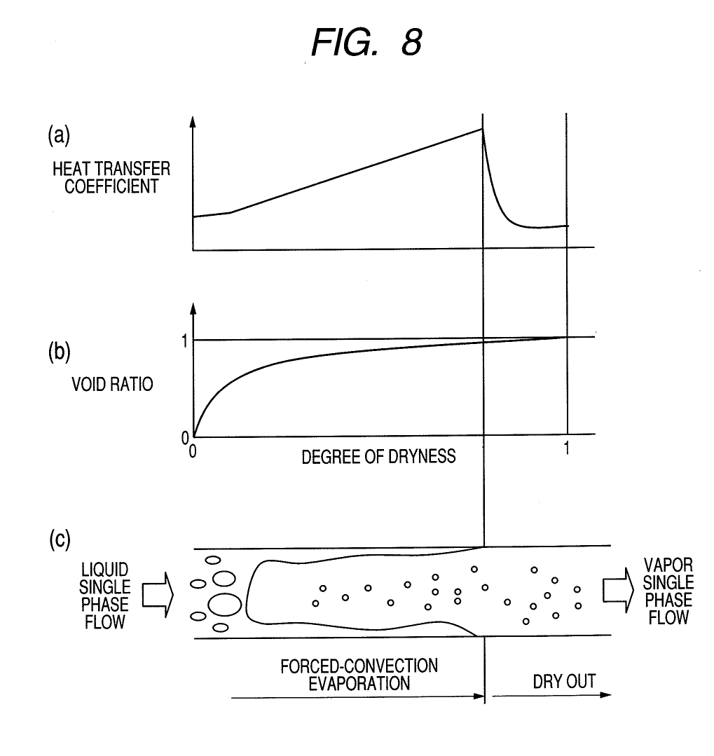

As the second embodiment according to the present invention, an embodiment wherein the present invention is applied to a plasma processing apparatus as a heat pump cycle to control temperature in both heating and cooling of a sample table is explained in reference to FIGS. 6 (FIGS. 6A and 6B) and 7.

When a heat pump cycle is used as a cooling cycle in the second embodiment, the basic configuration and function are the same as those of the cycle adopted in the first embodiment (refer to FIG. 1). An example of a switching mechanism of supply/discharge ports connected to a refrigerant flow passage 2 and controlled by a refrigerant supply/discharge direction switching control means 142 is shown in FIG. 6. The heat pump cycle includes a first heat exchanger (a refrigerant flow passage formed in a sample table 1) 2, a compressor 7, a second heat exchanger (a condenser) 8, a first expansion valve 9, a second expansion valve 10, and a refrigerant evaporating heater 11 (in a direct-expansion type refrigerant supply unit 60). Further, a bypass flow passage 14 and a control valve 27 are attached to the condenser 8, and a flow rate valve 16, a temperature controlling water tank 17, and others are installed in the middle of a cooling water flow passage 28 in the same manner as the first embodiment.

Meanwhile, when a heat pump cycle is used as a heating cycle, the switching of the supply/discharge ports connected to the refrigerant flow passage 2 is reversed from the case of the cooling cycle. Further, the first heat exchanger (the refrigerant flow passage formed in the sample table 1) 2 functions as a condenser and the second heat exchanger 8 (in the direct-expansion type refrigerant supply unit 60) functions as an evaporator. Consequently, a sample table temperature controller 100 has a heating/cooling operation controller 141 and a refrigerant supply/discharge direction switching control means 142 to switch the operation mode (heating cycle or cooling cycle), in addition to the functions shown in FIG. 1B, such as an integrating temperature controller, a first heat exchanger pressure and flow rate controller 102, a second heat exchanger heat exhausting capacity controller 103, a refrigerant heater controller 104, an electrostatic adsorption heat transfer gas controller 105, a first expansion valve opening degree controller 106, a second expansion valve opening degree controller 107, and a compressor rotation speed controller 108.

In the case where the cross-sectional area of the refrigerant flow passage 2 in the electrode is optimized in accordance with the change of the heat transfer coefficient of the refrigerant as shown in FIG. 2, the heat transfer coefficient is nearly constant in the refrigerant flow passage of the gas-liquid two-phase in the cooling cycle. For that purpose, as stated above, the cross-sectional area of the flow passage is increased, the flow rate of the refrigerant is reduced, and thereby the heat transfer coefficient of the refrigerant is lowered at a position where the heat transfer coefficient of the refrigerant is large in the general characteristic of a constant flow passage cross-sectional area. On the contrary, at a position where the heat transfer coefficient of the refrigerant is small, the heat transfer coefficient of the refrigerant is increased by reducing the flow passage cross-sectional area and increasing the flow rate of the refrigerant. By so doing, it is possible to flatten the value of the heat transfer coefficient from the entry to the exit of the refrigerant flow passage in the electrode.

In contrast, in the case where the refrigerant is used in a heating cycle, the change of the heat transfer coefficient of the refrigerant in the refrigerant flow passage 2 shows a characteristic opposite to the case of the cooling cycle. That is, the heat transfer coefficient takes the maximum value at the supply port of the refrigerant and the minimum value at the discharge port of the refrigerant during condensing and heat exhausting. Consequently, in order to uniformly heat the plane of the electrode in the heating cycle, it is necessary to reverse the supply port and the discharge port of the refrigerant in the refrigerant flow passage 2 from the case of the cooling cycle.

The direction of the refrigerant supplied to the refrigerant flow passage 2 can easily be switched by installing bypass pipes 5C and 5D to bypass the parts of refrigerant flow passages 5A (5A1 and 5A2) and 5B (5B1 and 5B2) and opening/closing valves 41 to 44 as shown in FIG. 6 (FIGS. 6A and 6B). That is, in the case of cooling cycle, as shown in FIG. 6A, the first valve 41 and the second valve 42 are opened, the third valve 43 and the fourth valve 44 are closed, the refrigerant flow passage 5A (5A1 and 5A2) is connected to a refrigerant supply port 3 on the center side of a sample table 1, the refrigerant flow passage 5B (5B1 and 5B2) is connected to a refrigerant discharge port 4 on the outer circumference side of the sample table 1 through a first heat exchanger (a refrigerant flow passage formed in the sample table 1) 2 functioning as an evaporator, and the refrigerant flow passage 5B is further connected to a second heat exchanger (an evaporator) 8 (in a direct-expansion type refrigerant supply unit 60). Further, in the case of heating cycle, as shown in FIG. 6B, the first valve 41 and the second valve 42 are closed, the third valve 43 and the fourth valve 44 are opened, the refrigerant flow passage 5A1, the bypass pipe 5C, and the refrigerant flow passage 5B1 are connected to the refrigerant supply port 4 on the outer circumference side, the refrigerant flow passage 5A2, the bypass pipe 5D, and the refrigerant flow passage 5B2 are connected to the refrigerant discharge port 3 on the center side of the sample table 1 through the first heat exchanger (the refrigerant flow passage formed in the sample table 1) 2 functioning as a condenser, and further connected to the second heat exchanger (the evaporator) 8 (in the direct-expansion type refrigerant supply unit 60).

Successively, a method for controlling the flow mode of the refrigerant when heating operation is carried out with a heating cycle according to the second embodiment is shown in FIG. 7. In the heating cycle, an electrode base material 1A is heated by condensing the refrigerant in a first heat exchanger, namely in the refrigerant flow passage 2, and thereafter transferring heat from the refrigerant to the electrode.

In the operation of the cycle, firstly the supply of heat exchanging water to a second heat exchanger 8 is stopped, the refrigerant is depressurized and evaporated with a refrigerant evaporating heater 11 by reducing a second expansion valve 10, and the adsorbed heat is condensed with the first heat exchanger 2 of the electrode base material 1A and exhausted. Here, a bypass flow passage 14 for a condenser may be installed in place of the stoppage of the supply of the heat exchanging water to the second heat exchanger 8. When the bypass flow passage 14 is used however, the refrigerant may stagnate in the condenser 8 in the cycle and the circulation volume of the refrigerant may reduce in the cycle.

In the heating cycle too, similarly to the cooling cycle, the temperature of the refrigerant changes in accordance with the change of the enthalpy in a liquid or gaseous state and hence it is possible to uniformly raise the in-plane temperature of the electrode, consequently the in-plane temperature of a wafer, by heating the refrigerant while keeping the refrigerant flow passage 2 in the gas-liquid two-phase state.

In order to keep the refrigerant flow passage 2 constituting the first heat exchanger in the gas-liquid two-phase state in the heating cycle, it is necessary to control the enthalpy of the vapor compressed with a compressor 7 and supplied into the refrigerant flow passage 2. To this end, the enthalpy that has increased to iI is lowered to iH for example by controlling the volume and the temperature of the heat exchanging water in the second heat exchanger 8 and the refrigerant is supplied to the refrigerant flow passage 2. Further, by controlling the rotation speed of the compressor 7 and thereby securing a sufficient circulation volume of the refrigerant required for the heating capacity in the heating cycle, it is possible to discharge the refrigerant having the enthalpy iG before thoroughly liquefied as shown in the figure from the refrigerant flow passage 2, keep the refrigerant flow passage 2 in the gas-liquid two-phase state, and uniformly heat the plane of the electrode, consequently the plane of a wafer.

In the present embodiment, it is possible to uniformly control the in-plane temperature of the electrode, consequently the in-plane temperature of a wafer, by adjusting the enthalpy of the refrigerant supplied into the electrode flow passage and keeping the flow mode of the refrigerant in the gas-liquid two-phase state in the refrigerant flow passage. More specifically, by controlling the condensing capacity of the refrigerant immediately before flowing into the electrode, it is possible to inhibit the excessive heat exchange between the refrigerant and the heat exchanging water, keep the flow mode of the refrigerant in the gas-liquid two-phase state in the refrigerant flow passage, and uniformly control the in-plane temperature of a sample to be processed.

In addition, it is possible to provide a temperature adjusting unit for a sample table capable of uniformly controlling the in-plane temperature of a wafer with a direct-expansion type cycle during high heat input etching where a high wafer bias electric power is applied.

### Third Embodiment

As the third embodiment of the present invention, an example of a direct-expansion type cycle equipped with void ratio measuring devices is explained in reference to FIGS. 8 to 10.

Firstly, the flow mode of the refrigerant used in the present embodiment is shown in FIG. 8. In FIG. 8, (a) shows the relationship between a degree of dryness and a heat transfer coefficient, (b) shows the relationship between a degree of dryness and a void ratio, and (c) shows the flow mode of the refrigerant in a cooling cycle. In general, a refrigerant of a hydrofluorocarbon type used in a cooling cycle shows the same trend as shown in FIG. 8. In the cooling cycle, the flow mode of the refrigerant changes from a liquid to a gas-liquid two-phase and then to a gas. On this occasion, bubbles, namely a void ratio, increases in the refrigerant in proportion to the change of the flow mode. The void ratio is 0 when the refrigerant is a liquid and is 1 when the refrigerant is thoroughly a gas. Consequently, when the refrigerant in the refrigerant flow passage 2 is required to be always kept in the gas-liquid two-phase state, it is necessary to measure the void ratios of the refrigerant supplied to the electrode and the refrigerant discharged from the electrode and then monitor and control the flow mode. A void ratio can be measured by a sensing pin method, an attenuation method with an X ray or a y ray, or the like. Here, dry out (disappearance of a liquid film) occurs before the refrigerant changes to a gas (thorough vaporization) and the heat transfer coefficient of the refrigerant drops rapidly. For that reason, when the gas-liquid two-phase state is monitored with the void ratio, it is necessary to know the void ratio at which dry out occurs beforehand and control the circulation volume of the refrigerant in the cycle so that the void ratio of the refrigerant discharged from the electrode may be lower than the limit of the occurrence of dry out.

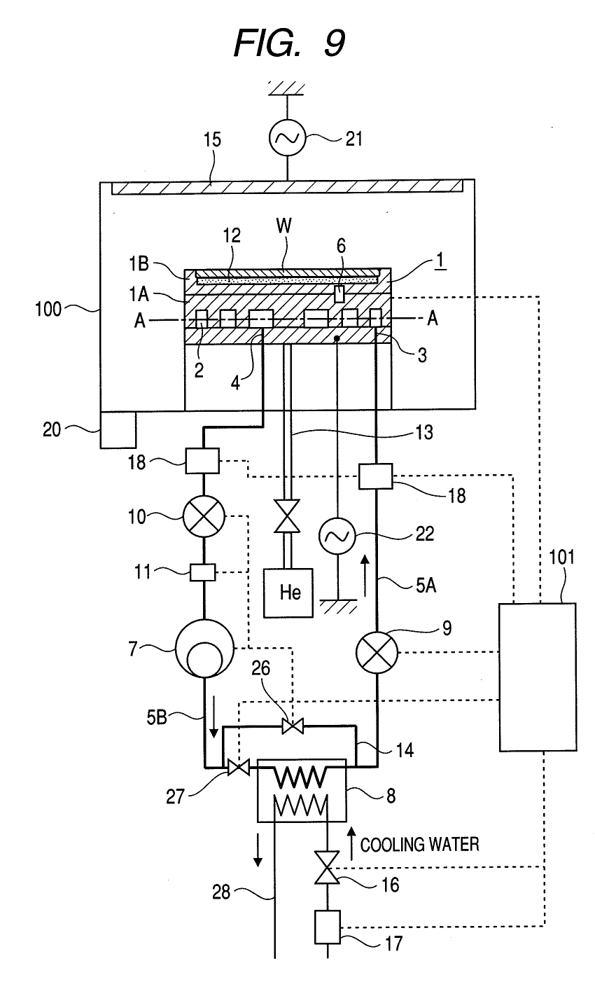

The general system configuration of a plasma processing apparatus according to the third embodiment of the present invention is shown in FIG. 9. The plasma processing apparatus according to the present embodiment includes void ratio measuring devices 18 as a means for measuring void ratios on the supply side and the discharge side of the refrigerant in the electrode flow passage in the cycle, in addition to the devices employed in the first embodiment.

The temperature of a wafer W varies in accordance with the conditions of processing such as plasma etching, namely a heat input state from plasma to the wafer W and a cooling or heating state by the refrigerant in the refrigerant flow passage 2. Temperature sensors are installed in the electrode and the circulation volume and the evaporation temperature of the refrigerant during the cooling or heating cycle are controlled with a sample table temperature controller 100.

Successively, the operations in the third embodiment are explained briefly. Firstly, a wafer W is conveyed into a processing chamber 30 and mounted on and fixed to a lower electrode 1. Secondly, a process gas is supplied and the processing chamber 30 is adjusted to a prescribed processing pressure. Then plasma is generated by the electric power supply from an antenna power source 21 and a bias power source 22 and the operation of a magnetic field forming means not shown in the figure, and etching is applied with the generated plasma. The temperature of the wafer in the process is controlled by carrying out feedback control with the sample table temperature controller 100 while monitoring temperature information sent from temperature sensors 6, adjusting the heat exhausting capacities of a compressor 7, a first expansion valve 9, a second expansion valve 10, and a condenser 8, and adjusting the flow rate and the evaporation temperature of the refrigerant.

On this occasion, void ratio measuring devices 18 to measure the void ratio of the refrigerant are installed at the electrode inlet and the electrode outlet and it is monitored that the refrigerant is kept in the gas-liquid two-phase state in the refrigerant flow passage 2. The measurement result of the void ratio is reflected to the control with the sample table temperature controller 100. If by any chance dry out of the refrigerant occurs in the refrigerant flow passage 2 because the heat input of plasma increases with time or by another reason, it is possible to inhibit the dry out from occurring in the refrigerant flow passage 2 by increasing the rotation speed of the compressor 7. Further, if the refrigerant supplied to the refrigerant flow passage 2 is liquefied, it is possible to keep the refrigerant supplied to the refrigerant flow passage 2 in the gas-liquid two-phase state by the control of the flow rate valve 16 for heat exchanging water and the temperature controlling water tank 17. By so doing, the refrigerant is always kept in the gas-liquid two-phase state in the refrigerant flow passage 2 and the in-plane temperature of a sample can be controlled uniformly and rapidly.

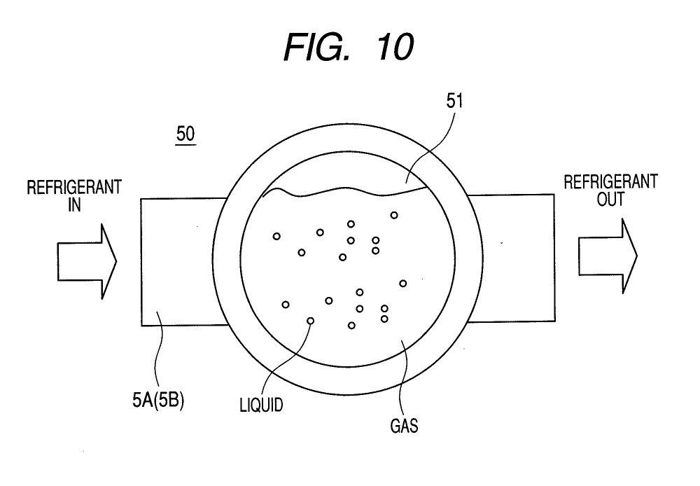

Here, it is unnecessary to measure a void ratio quantitatively but, when you want to know the flow mode or the flow state of the refrigerant easily, a sight glass or the like may be installed at the electrode inlet or the electrode outlet. The appearance of a sight glass is shown in FIG. 10. A sight glass 50 has a transparent window 51 made of glass or the like and it is possible to make parts of refrigerant flow passages 5A and 5B outside the sample table in the cycle transparent and thereby visually confirm the state of the refrigerant at an arbitrary position in the cycle. By the example shown in FIG. 10, it is observed that the refrigerant is in the gas-liquid two-phase state wherein the foams of gas exist in the liquid.

By adopting such a configuration and a control method, it is possible to process the whole plane of a wafer W with a high degree of accuracy even under a high heat input etching condition wherein a high wafer bias electric power is applied.

The etching is completed through such a process and the supply of electric power, magnetic fields, and a process gas is stopped.

Here, it goes without saying that the present invention is effective even when the plasma generating method is any one of the methods such as a method for applying a high-frequency electric power other than the electric power applied to a wafer W to the electrode installed in the manner of facing the wafer W, an inductive connection method, a method of interaction between a magnetic field and a high-frequency electric power, and a method for applying a high-frequency bias electric power to the sample table 1.

Further, the present invention is also effective when deep-hole processing of a high aspect such as an aspect ratio of 15 or more is applied in accordance with processing conditions of generating a high heat input such as the case where a high-frequency bias electric power of 3 W/cm² or more is applied to a wafer W. As a thin film for the plasma processing, a single layered film or a multilayered film including two or more kinds of films, such as a hardly workable dielectric film containing any one of SiO₂, Si₃N₄, SiOC, SiOCH, and SiC as the main component is envisaged.

Here, it goes without saying that the similar effects can be obtained in the case of the heating cycle according to the second embodiment too by incorporating void ratio measuring devices 18 and a sight glass in the cycle in the same way as the present embodiment.

In the present embodiment, it is possible to uniformly control the electrode in-plane temperature, consequently the wafer in-plane temperature, by adjusting the enthalpy of the refrigerant supplied to the electrode flow passage and keeping the flow mode of the refrigerant in the electrode flow passage in the gas-liquid two-phase state. More specifically, by controlling the condensing capacity of the refrigerant immediately before the refrigerator flows into the electrode, it is possible to inhibit excessive heat exchange between the refrigerant and the heat exchanging water, keep the flow mode in the refrigerant flow passage in the gas-liquid two-phase state, and uniformly control the in-plane temperature of a sample to be processed.

In addition, it is possible to provide a temperature adjusting unit for a sample table capable of uniformly controlling the in-plane temperature of a wafer with a direct-expansion type cycle during high heat input etching where a high wafer bias electric power is applied.

### Fourth Embodiment

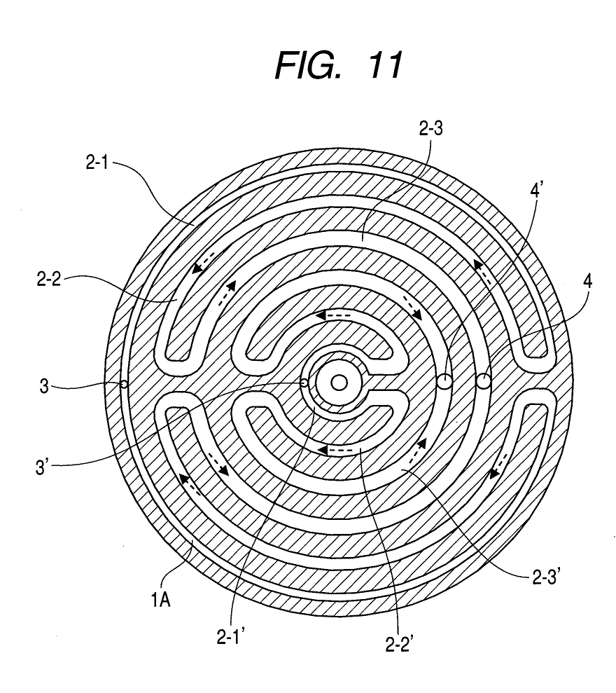

The present invention may be configured so that a refrigerant flow passage 2 may be diversified in the radial direction (from inside to outside) on the plane of a wafer. That is, as shown in FIG. 11, the refrigerant flow passage 2 has first flow passages 2-1 and 2-1′ respectively connected to two refrigerant supply ports 3 and 3′ located at different positions in the radial direction, second flow passages 2-2 and 2-2′ of larger cross-sections, and third flow passages 2-3 and 2-3′ of yet larger cross-sections, and the two third flow passages are respectively connected to two refrigerant discharge ports 4 and 4′ located at different positions in the radial direction. In the present embodiment, the diversified refrigerant flow passage 2 constitutes two evaporators (or the first heat exchanger in the heating cycle) of direct-expansion type cooling cycles independent from each other. That is, two refrigerant flow passages 2 are independent from each other in the plane and each of the refrigerant flow passages 2 functions as a part of each of the independent direct-expansion type cooling cycles. It is possible to arbitrarily control the in-plane temperature distribution of a wafer on a sample table 1 by separately controlling the refrigerant pressures (refrigerant evaporation temperatures) in the region of the refrigerant flow passage of each of the direct-expansion type cooling cycles. By so doing, it is possible to provide a temperature adjusting unit capable of rapidly and uniformly controlling the in-plane temperature of a wafer in a wide range during high heat input etching where a high wafer bias electric power is applied.

Further, in addition to the above embodiments, the present invention can also be applied to the case where a heater layer is installed in a dielectric film part. The temperature of a wafer varies in accordance with the conditions of processing such as plasma etching, namely the state of heat input from plasma to the wafer, the output power of each heater region, and the state of cooling by the refrigerant in the refrigerant flow passage 2. A temperature sensor is installed at each region of the hater layer and the electric power supplied from a heater electric source to each heater region, together with the flow rate of the refrigerant flowing in the flow passage 2 in the cooling cycle and others, is controlled with the sample table temperature controller 100.

### Fifth Embodiment

The present invention can also be applied to the case where a refrigerant flow passage formed in the sample table of a plasma processing apparatus is used as an evaporator and the cross-sectional area of the refrigerant flow passage is constant from a supply port to a discharge port. That is, it is possible to uniformly control the in-plane temperature of a sample to be processed by controlling the enthalpy of the refrigerant supplied to the refrigerant flow passage constituting an evaporator of the cooling cycle formed in a sample table of the plasma processing apparatus and thereby keeping the refrigerant flow passage, namely the flow mode in the sample table, in the gas-liquid two-phase state. Otherwise, in the case where the sample table of a plasma processing apparatus is used as a first heat exchanger and the heating cycle includes a compressor, a second heat exchanger, and an expansion valve, it is possible to uniformly control the in-plane temperature of a sample to be processed by controlling the enthalpy of the refrigerant supplied to the refrigerant flow passage and thereby keeping the flow mode in the refrigerant flow passage, namely in the sample table, in the gas-liquid two-phase state. For example, in the case of the heating cycle, in FIG. 7, in order to keep the refrigerant flow passage 2 in the gas-liquid two-phase state, it is necessary to control the enthalpy of the vapor compressed with the compressor 7 and supplied into the refrigerator flow passage 2. For the purpose, it is necessary to control the volume and the temperature of heat exchanging water of the second heat exchanger 8, thereby for example reduce the enthalpy which has increased to iI to iH, and supply the refrigerant to the refrigerant flow passage 2. Further, by controlling the rotation speed of the compressor 7 and thereby securing a sufficient circulation volume of the refrigerant required for the heating capacity in the heating cycle, it is possible to discharge the refrigerant having the enthalpy iG from the refrigerant flow passage 2 before thoroughly liquefied as shown in the figure, keep the refrigerant flow passage 2 in the gas-liquid two-phase state, and uniformly heat the plane of the electrode, consequently the plane of a wafer.

In the present embodiment, unlike the aforementioned embodiments, there is no function of controlling the flow rate of a refrigerant and inhibiting the heat transfer coefficient of the refrigerant from increasing in the region of the degree of dryness where the heat transfer coefficient of the refrigerant increases. As a result, the drawback in the present embodiment is that the increase of the heat transfer and the pressure loss of the refrigerant cannot be inhibited in the refrigerant flow passage 2 and the in-plane temperature of a sample to be processed on a sample table is hardly controlled uniformly, but the advantage thereof is that the forming of the refrigerant flow passage in the sample table is facilitated.

What is claimed is:

1. A plasma processing apparatus that has a sample table installed in a vacuum processing chamber, turns a process gas introduced into the vacuum processing chamber into a plasma gas, and applies surface processing with the plasma to a sample to be processed mounted on the sample table,
wherein a cooling cycle having a compressor, a condenser, and an expansion valve installed outside the vacuum processing chamber is structured while a refrigerant flow passage formed in the sample table is used as an evaporator of the cooling cycle;
wherein the refrigerant flow passage has a supply port and a discharge port formed in the sample table and the cross-sectional area of the refrigerant flow passage is formed so as to increase gradually from the supply port toward the discharge port;
wherein the plasma processing apparatus comprising:
a refrigerant evaporator controller to control the temperature and the flow rate of the refrigerant for temperature control supplied to and discharged from the refrigerant flow passage of the cooling cycle; and
a condensing capacity controller to control the heat exchanging capacity of the condenser; and
wherein the refrigerant for temperature control is controlled so that the refrigerant for temperature control supplied to the evaporator in the sample table may be kept in the state of a gas-liquid two-phase during the processing of the sample to be processed.

2. The plasma processing apparatus according to claim 1, wherein the condensing capacity controller has a means for controlling the flow rate of a medium for heat exchange supplied to the condenser.

3. The plasma processing apparatus according to claim 1, wherein the condensing capacity controller has a means for controlling the temperature of a medium for heat exchange supplied to the condenser.

4. The plasma processing apparatus according to claim 1,
wherein the plasma processing apparatus comprising a monitor that is installed in the heating cycle and monitors the flow mode of the refrigerant,
wherein the refrigerant for temperature control is controlled so that the refrigerant for temperature control supplied to the evaporator in the sample table may be kept in the state of a gas-liquid two-phase on the basis of the monitoring result with the monitor during the processing of the sample to be processed.

5. A plasma processing apparatus that has a sample table installed in a vacuum processing chamber, turns a process gas introduced into the vacuum processing chamber into a plasma gas, and applies surface processing with the plasma to a sample to be processed mounted on the sample table,
wherein a heating cycle having a compressor, a second heat exchanger, and an expansion valve installed outside the vacuum processing chamber is structured while a refrigerant flow passage formed in the sample table is used as a first heat exchanger;
wherein the refrigerant flow passage has a supply port and a discharge port formed in the sample table and the cross-sectional area of the refrigerant flow passage is formed so as to change gradually from the supply port toward the discharge port;
wherein the plasma processing apparatus comprising:
a means for switching the directions of the supply and discharge of the refrigerant to and from the refrigerant flow passage formed in the sample table in order to make it possible to switch the heating cycle to both the heating and cooling cycles;
a first heat exchanger controller to control the temperature and the flow rate of the refrigerant for temperature control supplied to and discharged from the refrigerant flow passage of the heating cycle; and
a second heat exchanger capacity controller to control the heat exchanging capacity of the second heat exchanger,
wherein the refrigerant for temperature control is controlled so that the refrigerant for temperature control supplied to the first heat exchanger in the sample table may be kept in the state of a gas-liquid two-phase during the processing of the sample to be processed.

6. The plasma processing apparatus according to claim 5, wherein the plasma processing apparatus has a bypass flow passage running in parallel with the second heat exchanger.

7. The plasma processing apparatus according to claim 6, wherein the second heat exchanger capacity controller has a function to control the capacity to condensate the refrigerant for temperature control flowing into the first heat exchanger.

8. The plasma processing apparatus according to claim 5, wherein the second heat exchanger capacity controller has a means for controlling the flow rate of a medium for heat exchange supplied to the second heat exchanger.

9. The plasma processing apparatus according to claim 5,
wherein the plasma processing apparatus has a monitor that is installed in the heating cycle and monitors the flow mode of the refrigerant; and
wherein the refrigerant for temperature control is controlled so that the refrigerant for temperature control supplied to the first heat exchanger in the sample table may be kept in the state of a gas-liquid two-phase on the basis of the monitoring result with the monitor during the processing of the sample to be processed.

10. The plasma processing apparatus according to claim 9, wherein the plasma processing apparatus has, as the monitors, void ratio measuring devices installed on both the refrigerant supply and discharge sides of the first heat exchanger in the cycle.

11. A plasma processing apparatus that has a sample table installed in a vacuum processing chamber, turns a process gas introduced into the vacuum processing chamber into a plasma gas, and applies surface processing with the plasma to a sample to be processed mounted on the sample table,
wherein a cooling cycle having a compressor, a condenser, and an expansion valve installed outside the vacuum processing chamber is structured while a refrigerant flow passage formed in the sample table is used as an evaporator;
wherein the plasma processing apparatus comprising:
a refrigerant evaporator controller to control the temperature and the flow rate of the refrigerant for temperature control supplied to and discharged from the refrigerant flow passage of the cooling cycle; and
a condensing capacity controller to control the heat exchanging capacity of the condenser,
wherein the refrigerant for temperature control supplied to the evaporator in the sample table is kept in the state of a gas-liquid two-phase by controlling the enthalpy of the refrigerant for temperature control supplied into the refrigerant flow passage during the processing of the sample to be processed.
